(19) United States
(12) Patent Application Publication
(10) Pub. No.: US 2026/0160841 A1
(43) Pub. Date: Jun. 11, 2026

(54) REINFORCEMENT LEARNING TO PREDICT MRI GRADIENT WAVEFORM PREEMPHASIS

(71) Applicant: Vanderbilt University, Nashville, TN (US)

(72) Inventors: Jonathan Martin, Nashville, TN (US); Kevin Harkins, Nashville, TN (US)

(21) Appl. No.: 19/183,307

(22) Filed: Apr. 18, 2025

Related U.S. Application Data
(60) Provisional application No. 63/635,777, filed on Apr. 18, 2024.

(51) Int. Cl. G01R 33/54; G06N 3/0442; G06N 3/092

(52) U.S. Cl. CPC G01R 33/543; G06N 3/0442; G06N 3/092

(57) ABSTRACT

An example system includes an MRI machine including a gradient coil; and a controller operably coupled to the MRI machine, where the controller is configured to: estimate a hidden error state of the MRI machine by a recurrent neural network; select a preemphasis gradient waveform based on a policy of a reinforcement learning agent and the hidden error state of the MRI machine; output a gradient waveform by the MRI machine; update a policy of the reinforcement learning agent based on the gradient waveform, and a reward function; determine an optimal gradient preemphasis for a next time step by the reinforcement learning agent; and control the gradient coil of the MRI machine based on the optimal gradient preemphasis.

### CROSS-REFERENCE TO RELATED APPLICATION

This application claims the benefit of U.S. Provisional Application No. 63/635,777, which was filed Apr. 18, 2024, and which is hereby incorporated by reference in its entirety.

### GOVERNMENT SUPPORT

This invention was made with government support under Grant No. EB001628 awarded by the National Institutes of Health. The government has certain rights in the invention.

### BACKGROUND

Magnetic resonance imaging (MRI) is a noninvasive type of medical imaging. MRI uses magnetic fields and radiofrequency (RF) pulses to cause protons (hydrogen nuclei) in the body to emit signals, that can then be measured to create an MRI image.

To determine the spatial location of a signal emitted by hydrogen nuclei, the magnetic fields of an MRI machine can be configured with controlled variations of the magnetic field along different axes of the machine. These controlled variations are referred to as “gradients” and are generally created by specialized gradient coils. The gradient of the magnetic field causes the resonance frequency (“Larmor frequency”) of the protons to be different at different locations along the gradient. Thus, only protons at certain locations along the gradient will have a resonance frequency matching the RF pulses. The use of gradient fields allows for imaging complex spatial structures in 3D by applying gradients on each axis and imaging different sections of the body.

Improvements to the control and application of gradient fields can improve MRI imaging systems and methods.

### SUMMARY

In some aspects, implementations of the present disclosure include a system including: an MRI machine including a gradient coil; and a controller operably coupled to the MRI machine, wherein the controller is configured to: estimate a hidden error state of the MRI machine by a recurrent neural network; select a preemphasis gradient waveform based on a policy of a reinforcement learning agent and the hidden error state of the MRI machine; output a gradient waveform by the MRI machine; update a policy of the reinforcement learning agent based on the gradient waveform, and a reward function; determine an optimal gradient preemphasis for a next time step by the reinforcement learning agent; and control the gradient coil of the MRI machine based on the optimal gradient preemphasis.

In some aspects, implementations of the present disclosure include a system, wherein the gradient waveform is measured by a current measurement of a gradient amplifier of the MRI machine.

In some aspects, implementations of the present disclosure include a system, wherein selecting, outputting, and updating are iteratively repeated to optimize the policy of the reinforcement learning agent.

In some aspects, implementations of the present disclosure include a system, wherein the MRI machine is configured to output the preemphasis gradient waveform at a time step, and the steps of selecting, outputting, and updating are repeated at each time step to optimize the policy of the reinforcement learning agent.

In some aspects, implementations of the present disclosure include a system, wherein the preemphasis waveform includes an intentional predistortion.

In some aspects, implementations of the present disclosure include a system, wherein the intentional predistortion includes a random distortion or a distortion selected based on the reinforcement learning policy.

In some aspects, implementations of the present disclosure include a system, wherein the recurrent neural network is trained to estimate hidden states by measuring a plurality of unique gradient waveforms.

In some aspects, implementations of the present disclosure include a system, wherein the plurality of unique gradient waveforms include a chirp waveform and a trapezoidal waveform.

In some aspects, implementations of the present disclosure include a system, wherein the recurrent neural network includes a long short-term memory layer.

In some aspects, implementations of the present disclosure include a system, wherein the reward function includes an error component, an effort component, a constraint component, and a survival component.

In some aspects, implementations of the present disclosure include a computer-implemented method of training a reinforcement learning agent to determine an optimal gradient preemphasis for an MRI machine, the method including: estimating a hidden error state of the MRI machine by a recurrent neural network; selecting a preemphasis gradient waveform based on a policy of the reinforcement learning agent and the hidden error state of the MRI machine; outputting a gradient waveform by the MRI machine; updating a policy of the reinforcement learning agent based on the gradient waveform, and a reward function; and determining the optimal gradient preemphasis for a next time step; and outputting the optimal gradient preemphasis to control a waveform generator of an MRI machine.

In some aspects, implementations of the present disclosure include a computer-implemented method wherein selecting, outputting, and updating are iteratively repeated to optimize the policy of the reinforcement learning agent.

In some aspects, implementations of the present disclosure include a computer-implemented method, wherein the MRI machine is configured to output the preemphasis gradient waveform at a time step, and the steps of selecting, outputting, and updating are repeated at each time step to optimize the policy of the reinforcement learning agent.

In some aspects, implementations of the present disclosure include a computer-implemented method, wherein the preemphasis waveform includes an intentional predistortion.

In some aspects, implementations of the present disclosure include a computer-implemented method, wherein the intentional predistortion includes a random distortion or a distortion selected based on the reinforcement learning policy.

In some aspects, implementations of the present disclosure include a computer-implemented method, wherein the recurrent neural network is trained to estimate hidden states by measuring a plurality of unique gradient waveforms.

In some aspects, implementations of the present disclosure include a computer-implemented method, wherein the plurality of unique gradient waveforms include a chirp waveform and a trapezoidal waveform.

In some aspects, implementations of the present disclosure include a computer-implemented method, wherein the recurrent neural network includes a long short-term memory layer.

In some aspects, implementations of the present disclosure include a computer-implemented method, wherein the reward function includes an error component, an effort component, a constraint component, and a survival component.

In some aspects, implementations of the present disclosure include a non-transitory computer readable medium having instructions stored thereon, that, wherein execution of the instructions by a processor of an MRI system cause the processor to: estimate a hidden error state of the MRI machine by a recurrent neural network; select a preemphasis gradient waveform based on a policy of the reinforcement learning agent and the hidden error state of the MRI machine; output a gradient waveform by the MRI machine; update a policy of the reinforcement learning agent based on the gradient waveform, and a reward function; and determine the optimal gradient preemphasis for a next time step; and output the optimal gradient preemphasis to control a waveform generator of an MRI machine.

It should be understood that the above-described subject matter may also be implemented as a computer-controlled apparatus, a computer process, a computing system, or an article of manufacture, such as a computer-readable storage medium.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The components in the drawings are not necessarily to scale relative to each other. Like reference numerals designate corresponding parts throughout the several views.

FIG. 1 illustrates an example schematic of an MRI machine and controller, according to implementations of the present disclosure.

FIG. 2 illustrates an example method of determining an optimal gradient preemphasis, according to implementations of the present disclosure.

FIG. 3A illustrates an example reinforcement learning system and method, according to implementations of the present disclosure.

FIG. 3B illustrates an example reinforcement learning system and method, according to implementations of the present disclosure.

FIG. 3C illustrates an example reinforcement learning system and method, according to implementations of the present disclosure.

FIG. 3D illustrates an example reinforcement learning system and method, according to implementations of the present disclosure.

FIG. 4 illustrates a gradient modulation transfer function (MTF) for one measured chirp displayed at three gradient amplitudes on a 7 T system, according to a study of an example implementation of the present disclosure.

FIG. 5A illustrates the effect of reward shaping at c₂=0, according to a study of an example implementation of the present disclosure.

FIG. 5B illustrates the effect of reward shaping at c₂=2.5×10⁻⁴, according to a study of an example implementation of the present disclosure.

FIG. 6 illustrates a timecourse of gradient error predicted by an RNN for the sample chirp pulse shown in FIG. 7A, according to a study of an example implementation of the present disclosure.

FIG. 7A illustrates timecourse plots of nominal, unprecompensated, and precompensated chirp waveforms, according to a study of an example implementation of the present disclosure.

FIG. 7B illustrates gradient amplitude error, according to a study of an example implementation of the present disclosure.

FIG. 8 illustrates an example computing device.

### DETAILED DESCRIPTION

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. While implementations will be described in the context of specific MRI machines and systems, it will become evident to those skilled in the art that the implementations are not limited thereto, but are applicable for any type of MRI system.

Magnetic resonance imaging (MRI) uses time-varying gradients in the main magnetic field to map the location of objects in space to an image. However, MRI machines nearly always have significant nonlinearities that produce distortions in the time-varying gradient fields. These distortions may be corrected by applying preemphasis to the time-varying field, for example by modifying the input to the gradient system to compensate for the system distortions and produce the desired output, which significantly improves image quality. However, gradient system distortions are nonlinear and time-varying, making the prediction of preemphasis a very challenging inverse problem.

Implementations of the present disclosure include systems, and methods for designing gradient waveform preemphasis using reinforcement learning and/or controlling MRI machines using the designed gradient waveform preemphasis. The implementations described herein are capable of correcting gradient distortions which are present on every magnetic resonance imaging system. Gradient distortions can be caused by imperfections in the gradient chain that creates the gradient waveform. The gradient chain can include gradient power amplifiers, gradient coils, gradient controllers, and/or a gradient cooling system, for example, and imperfections in any or all parts of the chain can cause the resulting gradient waveform to be imperfect. For example, implementations of the present disclosure include systems and methods for applying reinforcement learning to the problem of determining preemphasis to correct gradient distortions.

Reinforcement learning is a subtype of machine learning in which an agent learns optimal actions from ongoing interaction with a real or simulated environment. The example implementation described herein includes a reinforcement learning agent which learns from experience to predict the optimal nonlinear gradient preemphasis has been developed. The example system and methods can include repeated iteration of the following steps: 1) the reinforcement agent choosing some preemphasis gradient waveform, 2) measurement of the gradient waveform on the scanner, 3) updating the reinforcement learning agent's policy to provide preemphasis that better corrects the distortion. Thus a policy can be learned whereby the reinforcement agent can determine the optimal preemphasis at any given time, allowing for the adaptive correction of time varying nonlinear distortions.

An additional challenge in performing accurate preemphasis is that the error between the nominal waveform and preemphasized waveform can be unknown at the time of determining preemphasis for the next waveform. Implementations of the present disclosure further include recurrent neural networks (RNNs) that can be configured to model the unobservable state(s) and thereby improve gradient preemphasis.

Gradient trajectory errors can have a considerable negative impact on image quality in magnetic resonance imaging. Trajectory deviations produce artifacts in non-Cartesian acquisitions,¹ and distortions in magnetization profiles.² Most frequently, the gradient chain and its imperfections are modeled as a linear time-invariant system ³. Using a linear model, appropriate gradient pre-emphasis may be predicted and added to the nominal gradient waveform to produce the desired output ⁴. However, the success of such methods assumes linearity, and gradient systems may have substantial nonlinearities. The gradient response has been observed to have nonlinear dependence on the input waveform ⁵ and hardware heating ¹. Thus, nonlinear pre-emphasis approaches may be required to more completely correct gradient distortions.

Existing systems for applying reinforcement learning to MRI contexts assume a fully observable environment, in which all state information is available. ⁷⁻⁹ In practice, many realistic environments are partially observable, with important state information obscured. ¹⁰ Thus, existing systems fail to address the problems of real, partially-observable systems.

The example implementation overcomes the problems of existing systems by applying a reinforcement learning⁶ approach to predict gradient waveform pre-emphasis. In the case of gradient predistortion, what can be the most salient state information (the current timestep's error between nominal and preemphasized waveform) may only be known after the gradient waveform has been played out, not during its timecourse. To overcome this partial observability, the example implementation incorporates a recurrent neural network (RNN) to model unobservable states over the waveform timecourse.¹¹ Additionally, the present disclosure includes a study showing the ability of an example implementation including RL to pre-compensate gradient waveforms based upon gradient system measurements.³

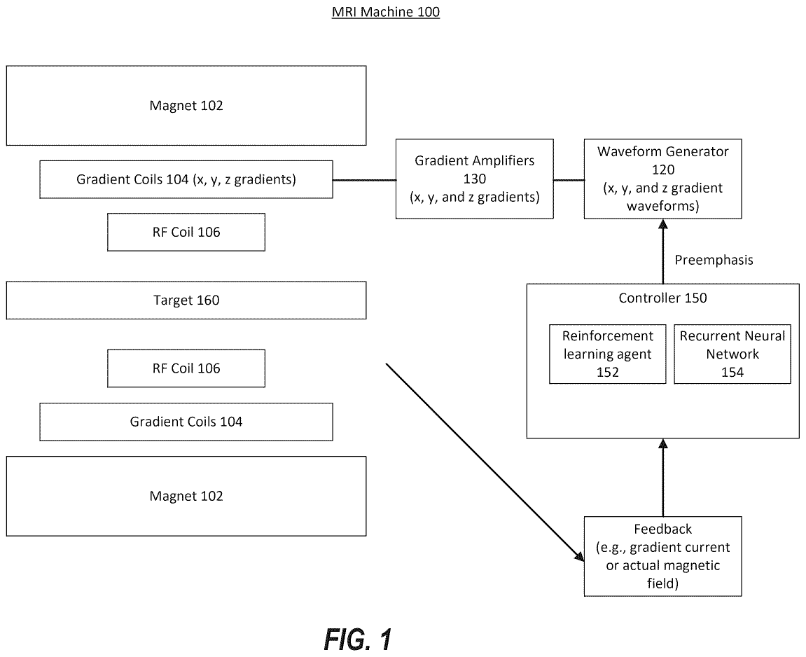

With reference to FIG. 1, an example block diagram of an MRI system is shown according to implementations of the present disclosure.

The example implementation includes an MRI machine 100 configured to be controlled by a controller 150. The MRI machine 100 can be any type of MRI machine, for example MRI machines configured for veterinary use (e.g., a 7 T small animal MRI system), for human use (e.g., a low-field 0.05 T human MRI system), or an MRI machine configured for research use.

The MRI machine 100 includes at least one magnet 102, gradient coils 104 (e.g., for x, y, and z gradient fields) and at least one RF coil 106. It should be understood that in practice, any combinations and numbers of coils can be used to implement any of the magnet 102, gradient coils 104, and RF coil 106, and that the spatial relationships and proportions of the coils can be different than what is shown in FIG. 1.

The MRI machine can further include gradient amplifiers 130 configured to drive the gradient coils, and waveform generator(s) 120 configured to output waveforms to drive the gradient amplifiers 130. As described herein, the gradient coils 104, gradient amplifiers 130, and waveform generator 120 can be collectively referred to as parts of a “gradient chain.” The gradient chain can optionally include other parts of the MRI machine (not shown) such as intermediate conductors and cooling devices. As described further above, and in the example below, the gradient chain can include nonlinearities, physical limitations, and imperfections that cause the gradient applied by the gradient coils 104 to be distorted, leading to imperfections in the resulting MRI image. For example, the gradient chain includes resistances and inductances that affect the output of the gradient coils 104.

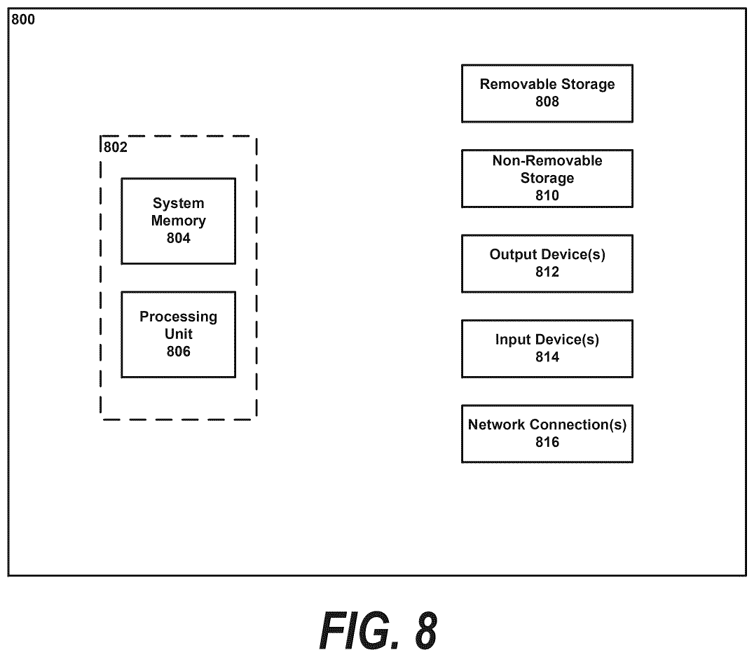

The system shown in FIG. 1 further includes a controller 150. The controller 150 can be a computing device (e.g., the computing device 800 of FIG. 8). Optionally, the controller 150 can be part of the MRI machine 100, but in some implementations the controller can be a separate computing device coupled to the MRI machine through a wired or wireless network.

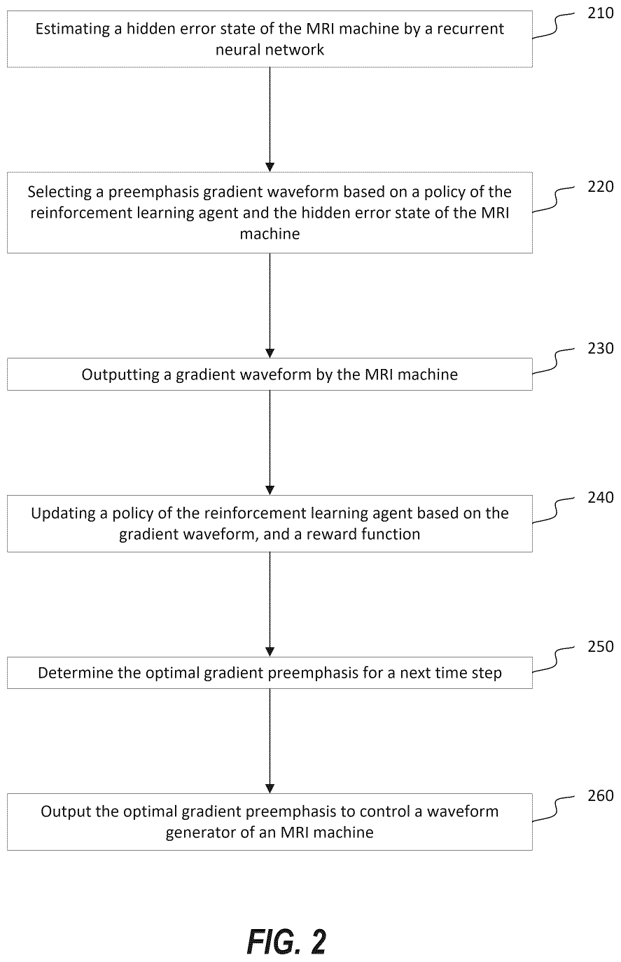

The controller 150 can include both a reinforcement learning agent 152 and a recurrent neural network 154. As described with reference to FIG. 2, herein, the reinforcement learning agent 152 and recurrent neural network 154 can implement methods of determining a preemphasis to be applied by the waveform generator 120. As used herein, preemphasis refers to modifying the nominal signal, so that the waveform generator 120 outputs a preemphasized signal. The preemphasized signal is configured to cause gradient coils 104 to produce a magnetic field that matches the nominal (intended) gradient defined by the waveform generator 120.

Still with reference to FIG. 1, the controller 150 can be configured to measure feedback from the MRI system as inputs to the reinforcement learning agent 152 and/or recurrent neural network 154. Non-limiting examples include indirect feedback (e.g., measurements of the current flowing through one or more gradient coils 104. Alternatively or additionally, direct feedback (e.g., the actual magnetic field at a target 160), can be used. An example of direct feedback includes using a pulse sequence to perform variable prephasing, where the pulse sequence used in the prephasing allows for measurement of the gradient waveform.

With reference to FIG. 2, an example method is shown according to implementations of the present disclosure. The example method can optionally be a computer-implemented method (e.g., as a computer-readable medium, or as a configuration of a controller or other computing device of an MRI system).

At step 210, the method includes estimating a hidden error state of the MRI machine by a recurrent neural network (RNN). A recurrent neural network is a type of neural network configured for data that is ordered/sequential data (e.g., making predictions based on prior data, and/or the order that data was received). Recurrent neural networks maintain a hidden state based on prior data, and can use the hidden state as a “memory” in predicting next elements in the ordered/sequential data. As used herein, a “policy” in the context of reinforcement learning refers to the strategy that the reinforcement learning agent uses to select a next action for a system (e.g., selecting preemphasis for the gradient waveform). Additionally, as used herein, a reinforcement learning “agent” can be a controller (e.g., a computing device with software implementing reinforcement learning algorithms), a software program (e.g., a program stored in memory and configured to perform reinforcement learning), and/or a computer model configured for reinforcement learning. Optionally, the reinforcement learning methods described herein can use a neural network (in addition to the recurrent neural network described below) to determine the policy of the agent. For example, the neural network used to determine the policy of the agent can be a temporal convolutional network. Alternatively or additionally, the policy of the agent can be determined by a measured system impulse response. As yet another example, the policy can be determined directly by interaction with the scanner. The interaction with the scanner can optionally be a rollout, as described herein.

Optionally, the recurrent neural network described herein can be trained to estimate hidden states of the imaging system (e.g., states of the imaging system that are not known in real time during imaging). For example, the recurrent neural network can include a long short-term memory layer.

The recurrent neural networks described herein can be trained by measuring unique gradient waveforms. As non-limiting examples, the unique gradient waveforms can include chirp waveforms and/or trapezoidal waveforms.

At step 220, the method includes selecting a preemphasis gradient waveform based on a policy of the reinforcement learning agent and the hidden error state of the MRI machine.

At step 230, the method includes outputting a gradient waveform by the MRI machine. As described with reference to FIG. 1, the gradient waveform can be output by gradient coils to generate a gradient field along one or more axes of the MRI machine.

At step 240, the method includes updating a policy of the reinforcement learning agent based on the gradient waveform, and a reward function. The reward function can include an error component, an effort component, a constraint component, and/or a survival component, as described with greater detail in the Example, below. The reinforcement learning algorithm can be configured with different objectives in various implementations of the present disclosure. Non-limiting examples of objectives for the reinforcement learning algorithm include minimizing error, minimizing image artifacts, and/or minimizing uncertainty in the system model.

The present disclosure can use both off-policy and on-policy reinforcement learning algorithms. As used herein, an off policy algorithm refers to an algorithm that can learn from data collected from strategies other than those selected by the reinforcement learning agent. Non-limiting examples of off-policy algorithms that can be used in implementations of the present disclosure include TD3 (Twin Delayed DDPG), DDPG (Deep Deterministic Policy Gradient), the Dreamer Algorithm, and SAC (Soft Actor-Critic). An on-policy algorithm is configured to learn from the current policy selected by the reinforcement learning agent. Non-limiting examples of on-policy algorithms that can be used in implementations of the present disclosure include Dreamer (e.g., Dreamer V3), PPO (Proximal Policy Optimization), and I2A (Imagination-Augmented Agents).

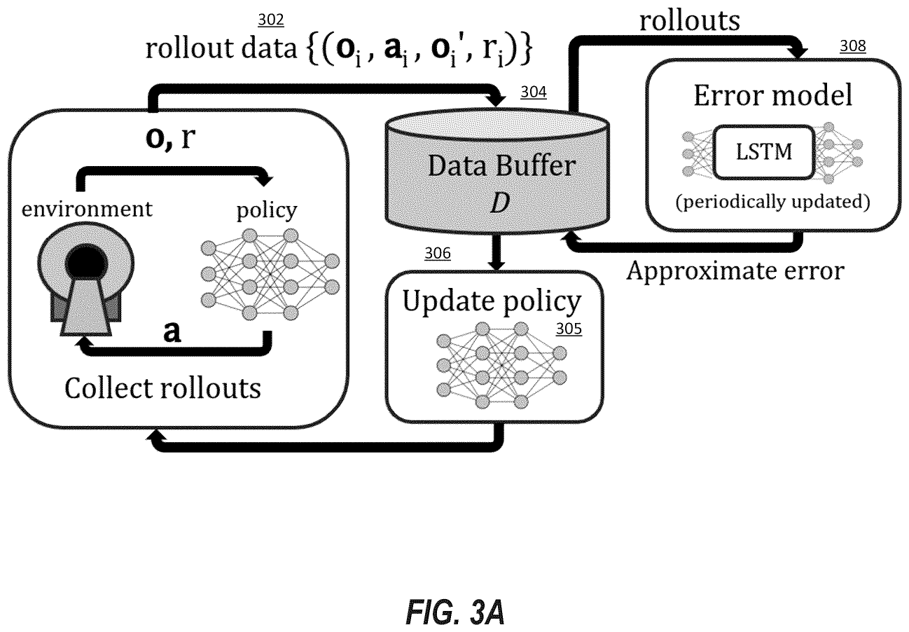

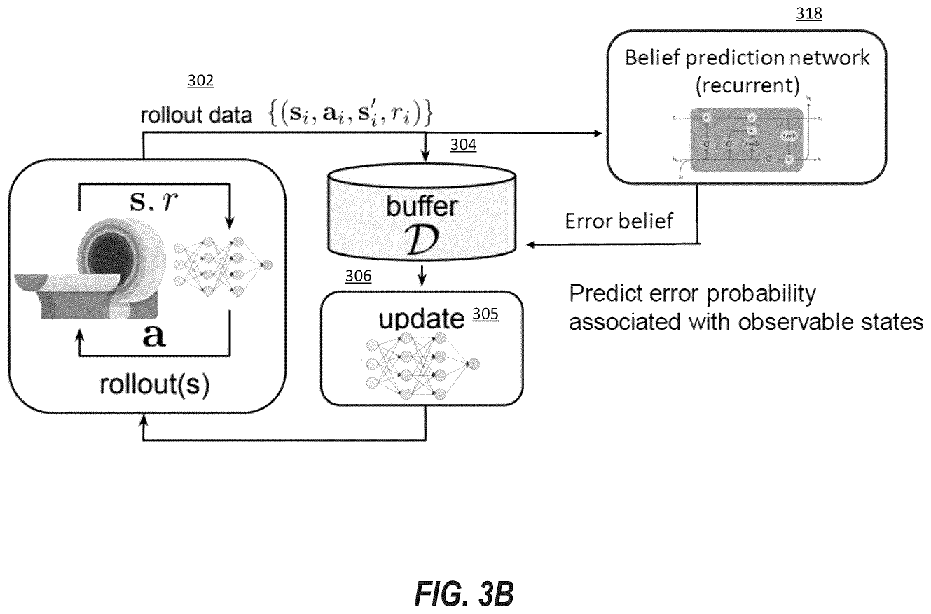

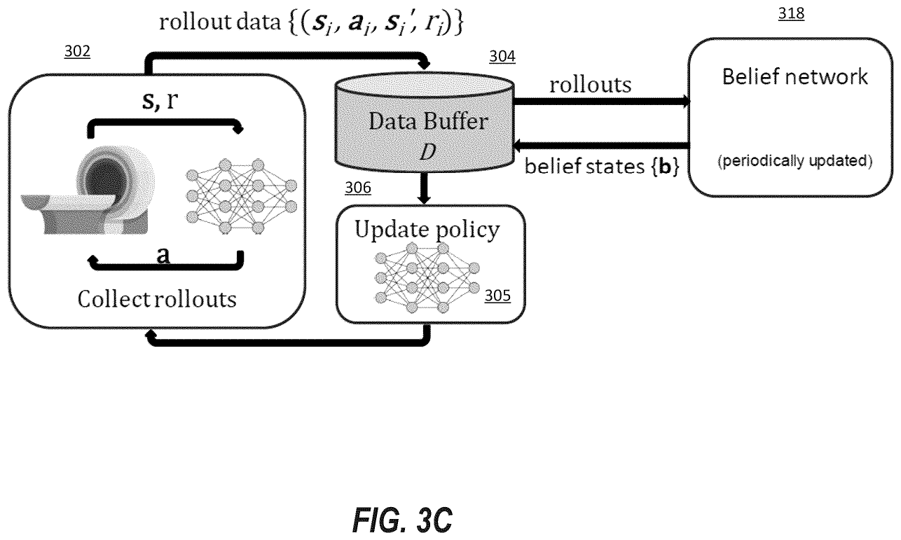

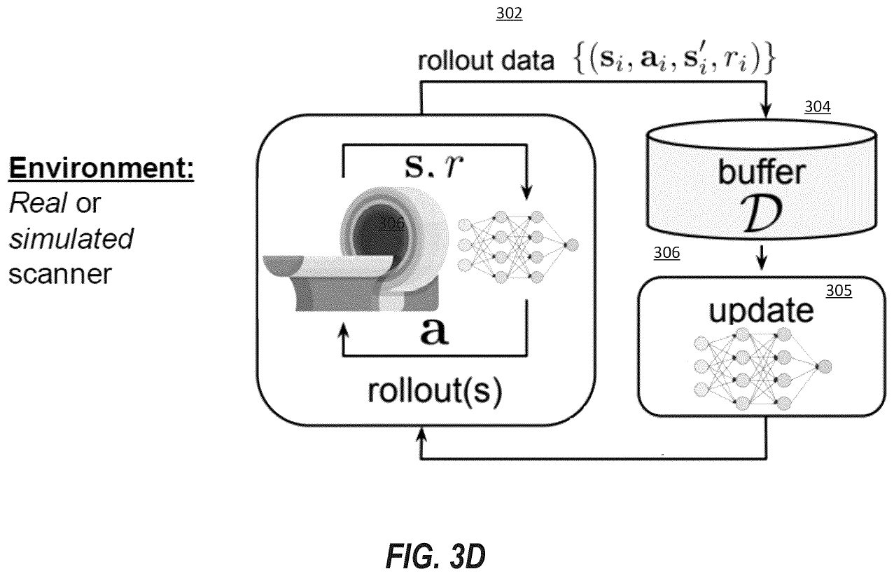

FIG. 3A illustrates an example reinforcement learning system and method that can be used in implementations of the present disclosure. In FIG. 3A, an off-policy algorithm is used, in which rollouts 302 of observation-action-observation-reward transitions are recorded and stored in a data buffer 304. As used herein, a “rollout” refers to an observation, action, reward, and subsequent observation. The contents of the data buffer 304 can be periodically used to update the neural network 305 determining the policy of the agent 306. An RNN 308 can be used as an error model to predict the gradient amplitude error across rollouts. By including the RNN 308, training of the agent 306 can optionally be performed without directly interacting with the scanner, saving machine time. Additional description of the example reinforcement learning system and method of FIG. 3A is provided in the Example, below.

FIG. 3B illustrates another example reinforcement learning system and method that can be used in implementations of the present disclosure. The implementation shown in FIG. 3B can include the rollouts 302, data buffer 304, neural network 305, and agent 306 described with reference to FIG. 3A. However, instead of the RNN 308 that acts as an error model, an belief prediction network 318 is used to estimate an error belief. As shown in FIG. 3B, the belief prediction network can optionally be a recurrent network. As used herein, an “error belief” is a guess about an unobserved part of the MRI system. Like the RNN 308 of FIG. 3A, the belief prediction network 318 can optionally allow for training of the agent 306 without direct interactions with the scanner, thereby saving machine time.

FIG. 3C illustrates another example reinforcement learning system and method that can be used in implementations of the present disclosure. The implementation shown in FIG. 3B can include the rollouts 302, data buffer 304, neural network 305, and agent 306 described with reference to FIG. 3A. However, in the implementation of FIG. 3C, the belief prediction network is periodically updated.

FIG. 3D illustrates another example reinforcement learning system and method that can be used in implementations of the present disclosure. In the implementation shown in FIG. 3D, the reinforcement learning systems and methods described herein can be used without using the belief network 318 or RNN 308 described with reference to FIGS. 3A-3C. The implementation shown in FIG. 3D can be trained using a real or simulated MRI system. However, as described herein, the implementation shown in FIG. 3D lacks the benefits of using an RNN 308 or belief prediction network 318 to model unobserved states of the system.

It should be understood that the implementations shown in FIGS. 3A-3D are intended as non-limiting examples, and that implementations of the present disclosure can include any combination of the following: 1. On-policy or Off-Policy Reinforcement learning algorithms; (2) reinforcement learning systems that are performed both with and without a belief network; and/or (3) with models of the gradient system that are not based on machine learning, where the non-machine learning models can be used in place of the belief network. One non-limiting example of a non-machine learning based model is a gradient system impulse response function (GIRF).At step 250, the method includes determining the optimal gradient preemphasis for a next time step.

At step 260, the method includes outputting the optimal gradient preemphasis to control a waveform generator of an MRI machine.

Any or all of the steps 210, 220, 230, 240, 250, and 260 can be iteratively repeated any number of times. For example, the policy of the reinforcement learning agent can be iteratively updated to optimize the gradient preemphasis determined based on the policy of the reinforcement learning agent.

Alternatively or additionally, any or all of the steps 210, 220, 230, 240, 250, and 260 can be performed at each time step of the MRI system. As used herein, a “time step” refers to the discrete points in time where measurements are acquired by the MRI system. The measurements can include gradient waveform, one dimensional signals, and/or signals related to MRI imaging. The “timecourse” described herein refers to a collection of time steps that are used to create a partial or complete MRI image. By completing the steps 210, 220, 230, 240, 250, and 260 during each time step, the methods and systems described herein can determine an optimized gradient preemphasis for the next time step while the previous time step is in progress.

In some implementations, the methods described herein can be used to train a reinforcement learning system to output optimized gradient preemphasis. For example, an intentional predistortion can be applied to the gradient waveform of the MRI machine to characterize the MRI machine using the reinforcement learning agent and/or RNN of the present disclosure. As non-limiting examples, the intentional predistortion can include random distortion(s) and/or distortion(s) selected based on the reinforcement learning policy of the reinforcement learning agent.

### Example

An example implementation of the present disclosure was designed and tested in a study.

Methods. An example implementation of an RL framework used for the study is shown in FIG. 3A.

The example implementation used an off-policy RL algorithm, TD3¹², was implemented using Stable Baselines3¹³ and hyperparameter tuning was performed with Optuna ¹⁴. The example implementation can use any of the off-policy RL algorithms described herein, including the Dreamer V3 algorithm. TD3 is configured with a policy which predicts the optimal next gradient preemphasis action a given a current observed system state o. The action space from which actions a at timepoint i are selected was continuous over (−1,1), and determined normalized change in gradient slew. The observation space was oᵢ=[slewᵢ/errorᵢ]. Only the slew; state is observable. To predict unobservable errorᵢ, a RNN with one LSTM layer and one fully connected layer was used to estimate error based on waveform history. This network was trained on 8 unique gradient waveforms, including chirps and trapezoids, measured on the 7 T system at 7 gradient amplitudes. To direct the agent to satisfy system constraints, reward shaping¹⁵ was used. The total timestep reward was rᵢ=c₁r_{error,i}+c₂r_{effort,i}+c₃r_{constraint,i}+c₄r_{survival,i}. To verify that the error modeling RNN adequately approximates hidden states, the RL agent was trained to develop a preemphasis policy under two different conditions: 1) with access to the exact error for errorᵢ, and 2) with the RNN's prediction of errorᵢ. Although the example implementation is described as using an off-policy RL algorithm, it should be understood that on-policy algorithms (e.g., PPO and others described herein) can be used in some implementations of the present disclosure.

An example training environment for the study was constructed from gradient waveform measurements on the z-axis of on a 7 T preclinical MRI system sold under the trademark Bruker BioSpec using variable prephasing.¹⁶ These measurements were used to build a GIRF gradient model.¹⁶ Training was performed using multiple measured chirp and trapezoidal gradient waveforms.¹⁷ Training was repeated with and without the effort reward term r_{effort,i} to demonstrate the impact of reward shaping.

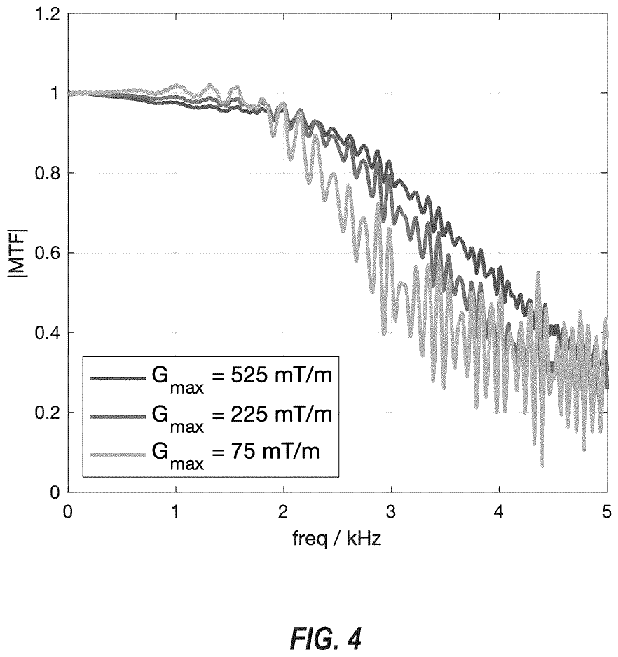

Results. FIG. 4 shows the gradient modulation transfer function measured on the system in the example method, which exhibits clear nonlinearity. The gradient modulation transfer function can vary depending on the amplitude of the input gradient waveform, showing nonlinearity of the gradient chain of the example MRI system used in the study.

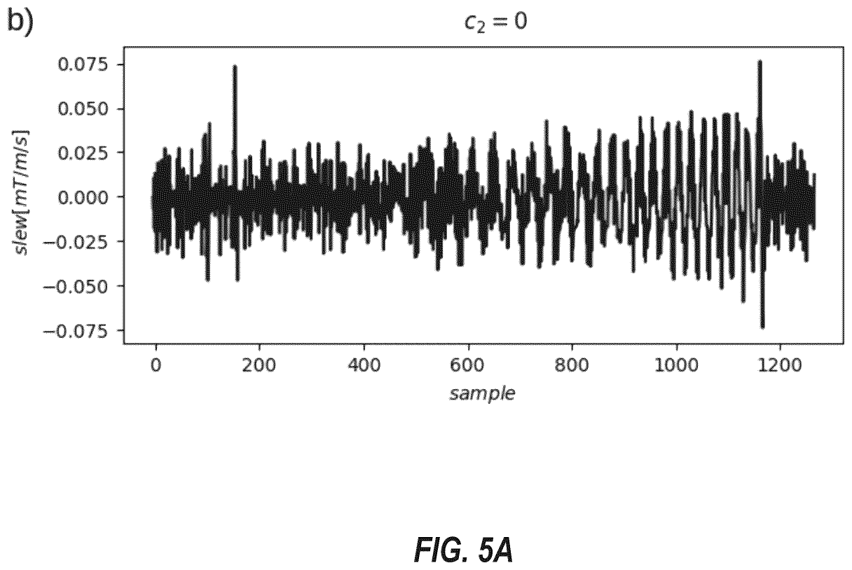

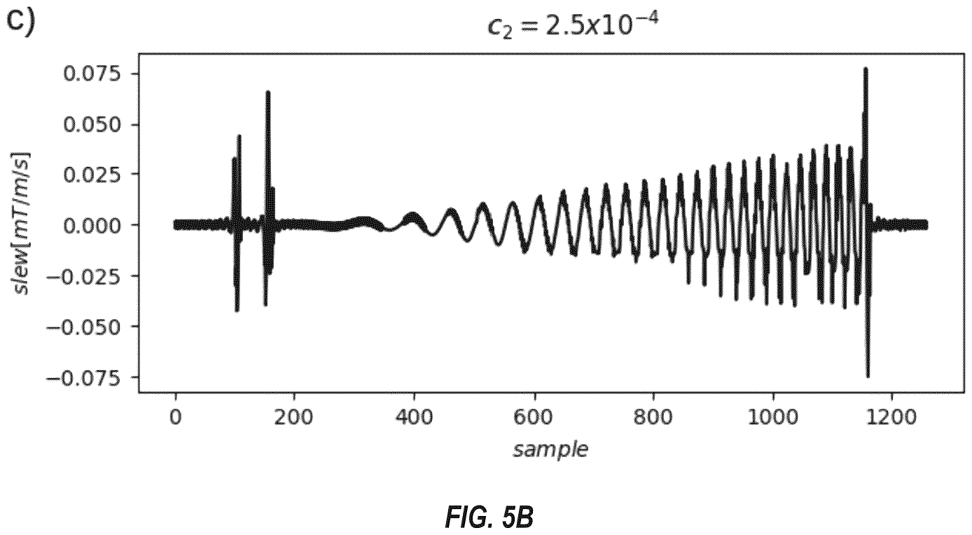

Table 1, below, defines the reward given to the agent at each timestep, while FIG. 5A and FIG. 5B show examples of the impact that reward shaping can have on the dynamics of the learned gradient control. If no effort penalty is imposed, the agent may create rough and/or unrealizable waveforms.

TABLE 1

| Term | Constants | Form |
|---|---|---|
| rₑᵣᵣₒᵣ | c₁ = 0.15 | e^{-c}^{ᵢ}^{∨Δg∨} |
| r_{effort} | c₂ = 2.5 × 10⁻⁴ | −c₂\|aᵢ − aᵢ₋₁\| |
| r_{constraint} | c₃ = 100 | −c₁ if max amp./slew violated |
| rₛᵤᵣᵥᵢᵥₑ | c₄ = 0.1 | c₄ |

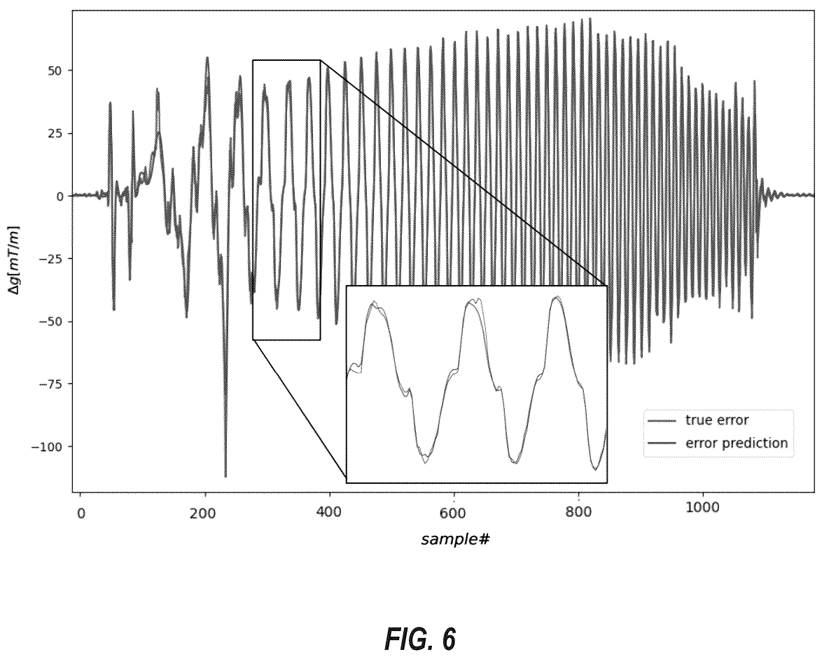

FIG. 6 shows that the error prediction RNN provides accurate estimation of error over a pulse's timecourse. Across 32 evaluation waveforms, the RNN achieved a test RMSE of 6.8E-3. FIG. 6 illustrates strong agreement between the true error and error predicted from partial state information. The RMSE for the illustrated prediction in FIG. 6 is 0.0611.

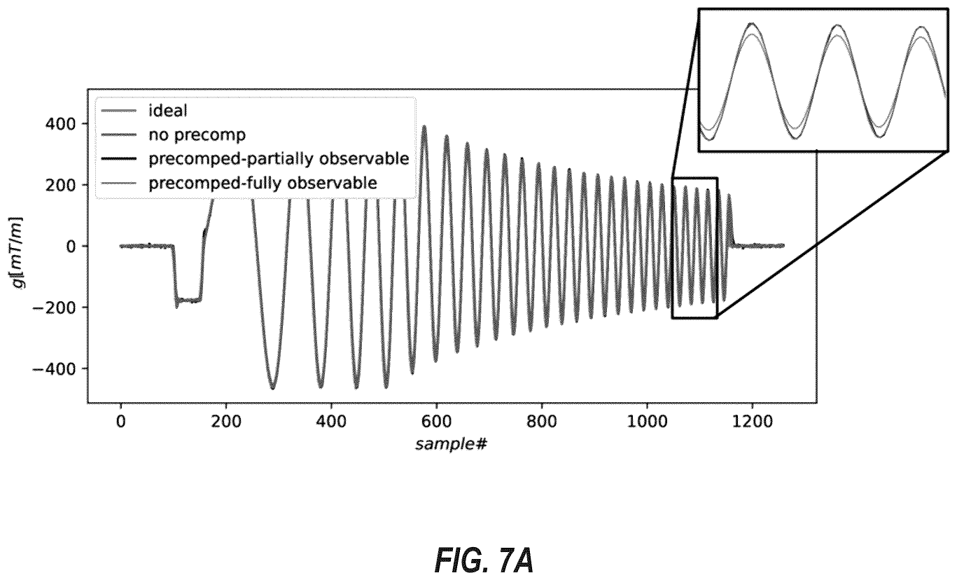

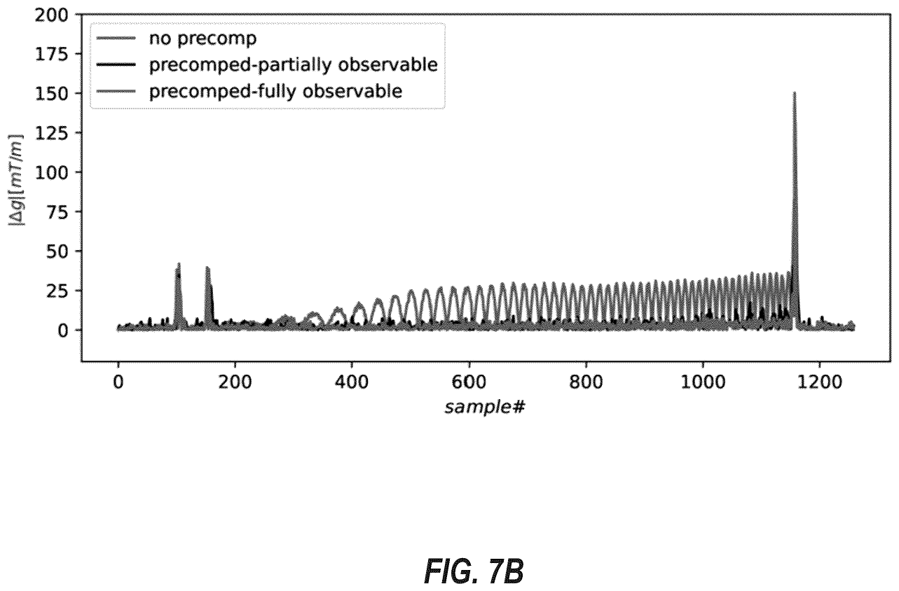

The learned predistortion of a test waveform is shown in FIG. 7A. The example TD3 RL agent learns precompensation slew which reduces the trajectory error to small values regardless of error state observability. FIG. 7B illustrates gradient amplitude error, where precompensation with either approach largely eliminates the error. As shown in FIG. 7B, the error is slightly larger in the partially observable case (RMSE=0.0643) than the fully observable case (RMSE=0.0593).

Discussion. This simulation of an example implementation of reinforcement-learning-based gradient preemphasis method described herein shows the feasibility of using RL to compensate for MRI system imperfections, including for temporally nonlinear gradient. The design of rewards is critical to the success of RL agents, and it was shown to have profound effects on the characteristics of the learned preemphasis. An adequate reward function should be designed for the task at hand. Partial observability is a challenging problem for RL algorithms that can make real-world implementation of RL agents impossible in many cases.¹⁰ This issue is rarely addressed in MRI applications of RL. The study shows that in the context of learned gradient preemphasis, partial observability can be overcome with a RNN predicting hidden states. This method provides a general framework for flexibly correcting nonlinear gradient distortions due to system nonlinearities and changing system response.

In the specification and/or figures, typical embodiments have been disclosed. The present disclosure is not limited to such exemplary embodiments. The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

It should be appreciated that the logical operations described herein with respect to the various figures may be implemented (1) as a sequence of computer implemented acts or program modules (i.e., software) running on a computing device (e.g., the computing device described in FIG. 8), (2) as interconnected machine logic circuits or circuit modules (i.e., hardware) within the computing device and/or (3) a combination of software and hardware of the computing device. Thus, the logical operations discussed herein are not limited to any specific combination of hardware and software. The implementation is a matter of choice dependent on the performance and other requirements of the computing device. Accordingly, the logical operations described herein are referred to variously as operations, structural devices, acts, or modules. These operations, structural devices, acts and modules may be implemented in software, in firmware, in special purpose digital logic, and any combination thereof. It should also be appreciated that more or fewer operations may be performed than shown in the figures and described herein. These operations may also be performed in a different order than those described herein.

Referring to FIG. 8, an example computing device 800 upon which the methods described herein may be implemented is illustrated. It should be understood that the example computing device 800 is only one example of a suitable computing environment upon which the methods described herein may be implemented. Optionally, the computing device 800 can be a handheld or laptop devices, multiprocessor systems, microprocessor-based systems, network personal computers (PCs), minicomputers, embedded systems, and/or distributed computing environments including a plurality of any of the above systems or devices. Distributed computing environments enable remote computing devices, which are connected to a communication network or other data transmission medium, to perform various tasks. In the distributed computing environment, the program modules, applications, and other data may be stored on local and/or remote computer storage media.

In its most basic configuration, computing device 800 typically includes at least one processing unit 806 and system memory 804. Depending on the exact configuration and type of computing device, system memory 804 may be volatile (such as random access memory (RAM)), non-volatile (such as read-only memory (ROM), flash memory, etc.), or some combination of the two. This most basic configuration is illustrated in FIG. 8 by dashed line 802. The processing unit 806 may be a standard programmable processor that performs arithmetic and logic operations necessary for operation of the computing device 800. The computing device 800 may also include a bus or other communication mechanism for communicating information among various components of the computing device 800.

Computing device 800 may have additional features/functionality. For example, computing device 800 may include additional storage such as removable storage 808 and non-removable storage 810 including, but not limited to, magnetic or optical disks or tapes. Computing device 800 may also contain network connection(s) 816 that allow the device to communicate with other devices. Computing device 800 may also have input device(s) 814 such as a keyboard, mouse, touch screen, etc. Output device(s) 812 such as a display, speakers, printer, etc. may also be included. The additional devices may be connected to the bus in order to facilitate communication of data among the components of the computing device 800. All these devices are well known in the art and need not be discussed at length here.

The processing unit 806 may be configured to execute program code encoded in tangible, computer-readable media. Tangible, computer-readable media refers to any media that is capable of providing data that causes the computing device 800 (i.e., a machine) to operate in a particular fashion. Various computer-readable media may be utilized to provide instructions to the processing unit 806 for execution. Example tangible, computer-readable media may include, but is not limited to, volatile media, non-volatile media, removable media and non-removable media implemented in any method or technology for storage of information such as computer readable instructions, data structures, program modules or other data. System memory 804, removable storage 808, and non-removable storage 810 are all examples of tangible, computer storage media. Example tangible, computer-readable recording media include, but are not limited to, an integrated circuit (e.g., field-programmable gate array or application-specific IC), a hard disk, an optical disk, a magneto-optical disk, a floppy disk, a magnetic tape, a holographic storage medium, a solid-state device, RAM, ROM, electrically erasable program read-only memory (EEPROM), flash memory or other memory technology, or magnetic storage devices.

In an example implementation, the processing unit 806 may execute program code stored in the system memory 804. For example, the bus may carry data to the system memory 804, from which the processing unit 806 receives and executes instructions. The data received by the system memory 804 may optionally be stored on the removable storage 808 or the non-removable storage 810 before or after execution by the processing unit 806.

It should be understood that the various techniques described herein may be implemented in connection with hardware or software or, where appropriate, with a combination thereof. Thus, the methods and apparatuses of the presently disclosed subject matter, or certain aspects or portions thereof, may take the form of program code (i.e., instructions) embodied in tangible media, hard drives, or any other machine-readable storage medium where, when the program code is loaded into and executed by a machine, such as a computing device, the machine becomes an apparatus for practicing the presently disclosed subject matter. In the case of program code execution on programmable computers, the computing device generally includes a processor, a storage medium readable by the processor (including volatile and non-volatile memory and/or storage elements), at least one input device, and at least one output device. One or more programs may implement or utilize the processes described in connection with the presently disclosed subject matter, e.g., through the use of an application programming interface (API), reusable controls, or the like. Such programs may be implemented in a high level procedural or object-oriented programming language to communicate with a computer system. However, the program(s) can be implemented in assembly or machine language, if desired. In any case, the language may be a compiled or interpreted language and it may be combined with hardware implementations.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

### REFERENCES

[1] Graedel N., Kasper L., Engel M., Nussbaum J., Wilm B., Pruessmann K., andVannesjo S., Feasibility of spiral fMRI based on an LTI gradient model. Neuroimage. 2020; 245 (1): 1-10.
[2] Tse D. H. Y., Wiggins C. J., and Poser B. A. Estimating and eliminating the excitation errors inbipolar gradient composite excitations caused by radiofrequency-gradient delay: Example of bipolarspokes pulses in parallel transmission. Magnetic Resonance in Medicine. 2017; 78 (5): 1883-1890.
[3] Vannesjo S., Haeberlin M., Kasper L., Pavan M., Wilm B., Barmet C., and Pruessmann K. Gradient System Characterization by Impulse Response Measurements with a Dynamic Field Camera. Magnetic Resonance in Medicine. 2013; 69:583-593.
[4] Ahn C, Cho Z. Analysis of the Eddy-Current Induced Artifacts and the Temporal Compensation in Nuclear Magnetic Resonance Imaging. IEEE TMI. 1991; 10:47-52.
[5] Nussbaum, J. Advanced Modeling of Gradient Systems in MRI. 2020; PhD. Thesis.
[6] Arulkamaran K., Deisenroth M., Brundage M., Bharath A. Deep Reinforcement Learning: A Brief Survey. 2017; 34 (6): 26-38.
[7] Zhu B., Liu J., Koonjoo N., Rosen B., Rosen M. AUTOmated pulse SEQuence generation (AUTOSEQ) using Bayesian reinforcement learning in an MRI physics simulation environment. Proc. Intl. Soc. Magn. Reson. Med. 2018; 26:438.
[8] Zheng D., Sandino C., Nishimura D., Vasanawala S., Cheng J. Reinforcement Learning for Online Undersampling Pattern Optimization. Proc. Intl. Soc. Magn. Reson. Med. 2019; 27:1092.
[9] Shin D., Kim Y., Oh C., An H., Park J., Kim J., Lee J. Deep Reinforcement Learning-Designed Radiofrequency Waveform in MRI. Nature Machine Intelligence. 2021 3:985-994.
[10] Liu Q., Chung A., Szepesvari C., Jin C. When Is Partially Observable Reinforcement Learning Not Scary? PMLR. 2022; 178:5175-5220.
[11] Meng L., Gorber R., Dana K. Memory-based Deep Reinforcement Learning for POMDPs. IEEE IROS. 2021; p5619-5626.
[12] Fujimoto S., van Hoof H., Meger D. Addressing Function Approximation Error in Actor-Critic Methods. ICML. 2018; 35:1-15.
[13] Raffin A., Hill A., Gleave A., Kanervisto A., Ernestus M., Dormann N. Stable-Baselines3: Reliable Reinforcement Learning Implementations. JMLR. 2021; 22:1-8.
[14] Akiba T., Sano S., Yanase T., Ohta T., Koyama M. Optuna: A Next-Generation Hyperparameter Optimization Framework. Proc. KDD. 2019; 25:26232631.
[15] Grzes, M. Reward Shaping in Episodic Reinforcement Learning. AAMAS. 2017; 16:565-573. [16] Addy N., Wu H., Nishimura D. Magnetic Resonance in Medicine. 2011; 68 (1): 120-129.
[16] Harkins D., Does M. Efficient Gradient Waveform Measurements with Variable-Prephasing. J Magn. Reson. 2021; 327:106945.
[17] Addy N., Wu H., Nishimura D. Simple Method for MR Gradient System Characterization and k-space Trajectory Estimation. Magnetic Resonance in Medicine. 2011; 68 (1): 120-129.

1. A system comprising:
an MRI machine comprising a gradient coil; and
a controller operably coupled to the MRI machine, wherein the controller is configured to:
estimate a hidden error state of the MRI machine by a recurrent neural network;
select a preemphasis gradient waveform based on a policy of a reinforcement learning agent and the hidden error state of the MRI machine;
output a gradient waveform by the MRI machine;
update a policy of the reinforcement learning agent based on the gradient waveform, and a reward function;
determine an optimal gradient preemphasis for a next time step by the reinforcement learning agent; and
control the gradient coil of the MRI machine based on the optimal gradient preemphasis.

2. The system of claim 1, wherein the gradient waveform is measured by a current measurement of a gradient amplifier of the MRI machine.

3. The system of claim 1, wherein selecting, outputting, and updating are iteratively repeated to optimize the policy of the reinforcement learning agent.

4. The system of claim 1, wherein the MRI machine is configured to output the preemphasis gradient waveform at a time step, and the steps of selecting, outputting, and updating are repeated at each time step to optimize the policy of the reinforcement learning agent.

5. The system of claim 1, wherein the preemphasis waveform comprises an intentional predistortion.

6. The system of claim 5, wherein the intentional predistortion comprises a random distortion or a distortion selected based on the reinforcement learning policy.

7. The system of claim 1, wherein the recurrent neural network is trained to estimate hidden states by measuring a plurality of unique gradient waveforms.

8. The system of claim 7, wherein the plurality of unique gradient waveforms comprise a chirp waveform and a trapezoidal waveform.

9. The system of claim 1, wherein the recurrent neural network comprises a long short-term memory layer.

10. The system of claim 1, wherein the reward function comprises an error component, an effort component, a constraint component, and a survival component.

11. A computer-implemented method of training a reinforcement learning agent to determine an optimal gradient preemphasis for an MRI machine, the method comprising:
estimating a hidden error state of the MRI machine by a recurrent neural network;
selecting a preemphasis gradient waveform based on a policy of the reinforcement learning agent and the hidden error state of the MRI machine;
outputting a gradient waveform by the MRI machine;
updating a policy of the reinforcement learning agent based on the gradient waveform, and a reward function; and
determining the optimal gradient preemphasis for a next time step; and
outputting the optimal gradient preemphasis to control a waveform generator of an MRI machine.

12. The computer-implemented method of claim 11 wherein selecting, outputting, and updating are iteratively repeated to optimize the policy of the reinforcement learning agent.

13. The computer-implemented method of claim 11, wherein the MRI machine is configured to output the preemphasis gradient waveform at a time step, and the steps of selecting, outputting, and updating are repeated at each time step to optimize the policy of the reinforcement learning agent.

14. The computer-implemented method of claim 11, wherein the preemphasis waveform comprises an intentional predistortion.

15. The computer-implemented method of claim 14, wherein the intentional predistortion comprises a random distortion or a distortion selected based on the reinforcement learning policy.

16. The computer-implemented method of claim 11, wherein the recurrent neural network is trained to estimate hidden states by measuring a plurality of unique gradient waveforms.

17. The computer-implemented method of claim 16, wherein the plurality of unique gradient waveforms comprise a chirp waveform and a trapezoidal waveform.

18. The computer-implemented method of claim 11, wherein the recurrent neural network comprises a long short-term memory layer.

19. The computer-implemented method of claim 11, wherein the reward function comprises an error component, an effort component, a constraint component, and a survival component.

20. A non-transitory computer readable medium having instructions stored thereon, that, wherein execution of the instructions by a processor of an MRI system cause the processor to:
estimate a hidden error state of the MRI system by a recurrent neural network;
select a preemphasis gradient waveform based on a policy of a reinforcement learning agent and the hidden error state of the MRI system;
output a gradient waveform by the MRI system;
update a policy of the reinforcement learning agent based on the gradient waveform, and a reward function; and
determine an optimal gradient preemphasis for a next time step; and
output the optimal gradient preemphasis to control a waveform generator of an MRI system.
